(19) United States
(12) Patent Application Publication
(10) Pub. No.: US 2024/0353447 A1
(43) Pub. Date: Oct. 24, 2024

(54) TEST AND MEASUREMENT INSTRUMENT WITH INTEGRATED ANALOG FRONT END

(71) Applicant: Tektronix, Inc., Beaverton, OR (US)

(72) Inventors: Daniel G. Knierim, Beaverton, OR (US); Josiah A. Bartlett, Forest Grove, OR (US); Charles Adrian Hwang, Wheat Ridge, CO (US); Mark A. Norris, Louisville, CO (US)

(73) Assignee: Tektronix, Inc., Beaverton, OR (US)

(21) Appl. No.: 18/645,352

(22) Filed: Apr. 24, 2024

Related U.S. Application Data
(60) Provisional application No. 63/461,571, filed on Apr. 24, 2023.

(51) Int. Cl. G01R 13/02

(52) U.S. Cl. CPC G01R 13/0218

(57) ABSTRACT

A test and measurement instrument having an integrated analog front end that includes one or more amplifiers, the one or more amplifiers implemented on a high-speed amplifier integrated circuit die, a controlled-impedance signal path between an input and a reference voltage, the controlled-impedance signal path including one or more signal taps and one or more controlled-impedance attenuator stages, the one or more controlled-impedance attenuator stages implemented on the amplifier integrated circuit die, and a switching network structured to selectively couple a signal tap of the controlled-impedance signal path to a respective amplifier of the one or more amplifiers, the switching network implemented on the amplifier integrated circuit die

### CROSS-REFERENCE TO RELATED APPLICATIONS

This disclosure claims benefit of U.S. Provisional Application No. 63/461,571, titled “AMPLIFIER INPUT WITH INTEGRATED ATTENUATOR SWITCHING TOPOLOGY,” filed on Apr. 24, 2023, the disclosure of which is hereby incorporated herein by reference in its entirety.

### TECHNICAL FIELD

This disclosure relates to test and measurement instruments, and more particularly to an analog front end for a test and measurement instrument such as an oscilloscope.

### BACKGROUND

An oscilloscope Analog Front End (AFE) is generally responsible for amplifying and/or attenuating the customer's input signal as necessary to achieve the optimal amplitude to drive the Analog Digital Converter (ADC). This is generally accomplished with a combination of a programmable gain amplifier preceded by a switched attenuator (which serves to reduce large input amplitudes as necessary to fit within the break-down voltage and/or slew-rate limitations of the amplifier's input stage). For high-speed (multi-GHz) applications, this attenuator is generally implemented in a controlled-impedance (e.g. 50Ω) environment to minimize reflections between the attenuator and amplifier.

Many techniques have been considered for switching such attenuators, including electro-mechanical relays (e.g. conventional, slab-line, MEMS, etc.), solid-state (e.g. FET) relays, and PIN-diode switches. The electro-mechanical approaches are often large, expensive, and/or less reliable than desired, while the solid-state implementations tend to provide poorer performance metrics (insertion loss, return loss, cross-talk, etc.) and may not handle DC signal content well (as it would change the switching device bias conditions).

A standard Figure of Merit for solid-state switching devices is the product R_{ON}·C_{OFF} which is to first order independent of device scaling. Larger devices will have lower R_{ON} (which helps minimize insertion loss driving the controlled-impedance load) but also higher C_{OFF} (which increases HF crosstalk through an “open” switch). The R_{ON}·C_{OFF} product fundamentally limits the HF performance of a controlled-impedance switch topology.

### BRIEF DESCRIPTION OF THE DRAWINGS

FIG. 1 is a block schematic diagram of a test and measurement instrument having a tightly integrated analog front end according to embodiments of the disclosure.

FIG. 2 is a block schematic diagram illustrating an example integrated analog front end, according to embodiments of the disclosure.

### DETAILED DESCRIPTION

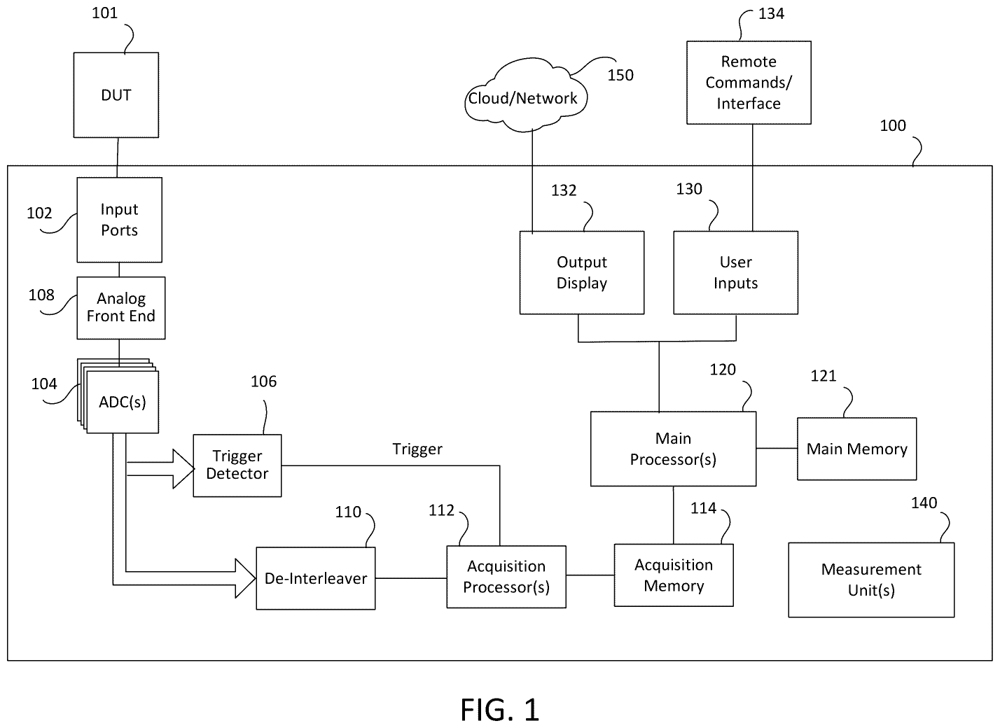

FIG. 1 is an example block diagram of a test and measurement instrument 100, such as an oscilloscope, having a tightly integrated analog front end (AFE) 108 according to embodiments of the disclosure. The test and measurement instrument 100 includes one or more ports 102, which may be any electrical or optical signaling medium. Ports 102 may include receivers, transmitters, and/or transceivers. Each port 102 is connected to a channel of the test and measurement instrument 100. In some embodiments the test and measurement instrument 100 includes 8, 16, or more separate ports. The test and measurement instrument 100 may couple to a Device Under Test (DUT) 101 through one or more ports 102. DUTs 101 that have multiple outputs may connect each output to the instrument 100 through multiple, independent ports 102.

The input signals received at the ports 102 are then sent to the analog front end 108, which performs signal conditioning on the input signals. The conditioned input signals are then input to one or more ADCs 104. As mentioned above, generally, the analog front end (AFE) 108 attenuates the input signals and/or amplifies the input signals in order to optimally use the dynamic range of the ADCs 104. In various embodiments, there may be multiple AFEs 108, each connected to a different input port 102 to condition the input signal received at that port. The attenuated/amplified analog signal from an AFE 108 may then be output to one or more ADCs 104. The ADCs 104 convert an analog signal received through the one or more ports 102 to digital data that represents the input signal. In some embodiments ADCs 104 may have an interleaved structure. Interleaving ADCs means that each individual ADC of the interleaved ADCs 104 processes only a portion of the data from the input port 102/AFE 108. The ADCs 104 have a sampling rate that is sufficient to sample the input signals with enough resolution to be usable by the instrument 100, and may be 8-bit, 12-bit, or higher resolution ADCs 104. Output data from the interleaved ADCs 104 is recombined in a de-interleaver 110 to produce the full-bandwidth signal received by the instrument 100.

In some embodiments, the digitized output of ADCs 104 is also coupled to a trigger detector 106. Trigger detector 106 is structured to monitor the digitized input signal(s) and detect when a trigger event occurs in one or more of the input signal(s). Trigger events may be specified by a user through user inputs 130, for example. When a trigger event is detected, the trigger detector 106 outputs a trigger signal, which may be used by the acquisition processor 112 to determine which information from the DUT is stored in an acquisition memory 114 as an input waveform for measuring and testing the DUT.

The acquisition memory 114 may be a relatively large memory that is structured to quickly store large amounts of incoming data. The acquisition memory 114 may be implemented as volatile memory or as solid-state memory, such as a solid-state disk drive(s).

The instrument 100 also includes one or more main processors 120 configured to execute instructions from main memory 121 and may perform any methods and/or associated steps indicated by such instructions.

User inputs 130 are coupled to the one or more processors 120, and may include a keyboard, mouse, touchscreen, and/or any other controls employable by a user to interact with a GUI on an output display 132. In some embodiments the user inputs 130 may be connected to or controlled by a remote interface 134, so that a user may control operation of the instrument 100 in a remote location physically away from the instrument. The display 132 may be a digital screen such as an LCD, or any other monitor to display waveforms, measurements, and other data to a user. In some embodiments, the output display 132 is also located remote from the instrument 100.

One or more measurement units 140 are illustrated as being part of the instrument 100. These measurement units 140 perform the main functions of measuring parameters and other qualities of signals from the DUT 101 being measured by the instrument 100. Typical measurements include measuring voltage, current, and power of input signals in the time domain, as well as measuring features of the input signals in the frequency domain. The measurement units 140 represent any measurements that are typically performed on test and measurement instruments.

While the components of the test and measurement instrument 100 are depicted as being integrated within test and measurement instrument 100, it will be appreciated by a person of ordinary skill in the art that any of these components can be external to the test and measurement instrument 100 and can be coupled to the test and measurement instrument 100 in any conventional manner (e.g., wired and/or wireless communication media and/or mechanisms). For example, in some examples, the display 132 may be remote from the test and measurement instrument 100, or data or images from the output of the instrument may be made available to other devices through a cloud or other type of communication network 150.

Embodiments of the disclosure include a test and measurement instrument 100 having an analog front end 108 that tightly integrates an attenuator network and associated switching on a high-speed amplifier die. This allows the attenuator to be placed physically close enough to the amplifier to allow the switching to be done outside the controlled-impedance signal path. Specifically, the signal path may be permanently routed through one or more controlled-impedance attenuators, and the switching network placed between variously-attenuated signal taps and one or more amplifier inputs. A switch's Rox is now driving a nominally high-impedance amplifier input rather than a controlled-impedance line, and a switch's C_{OFF} can be nominally matched to the amplifier's input capacitance C_{IN} and compensated with the same T-coil or other inductive peaking as was already needed for the amplifier. This significantly decouples attenuator switching performance from the R_{ON}·C_{OFF} Figure of Merit, allowing higher performance even within the restriction of using switching devices present on the same semiconductor process chosen for the high-speed amplifier.

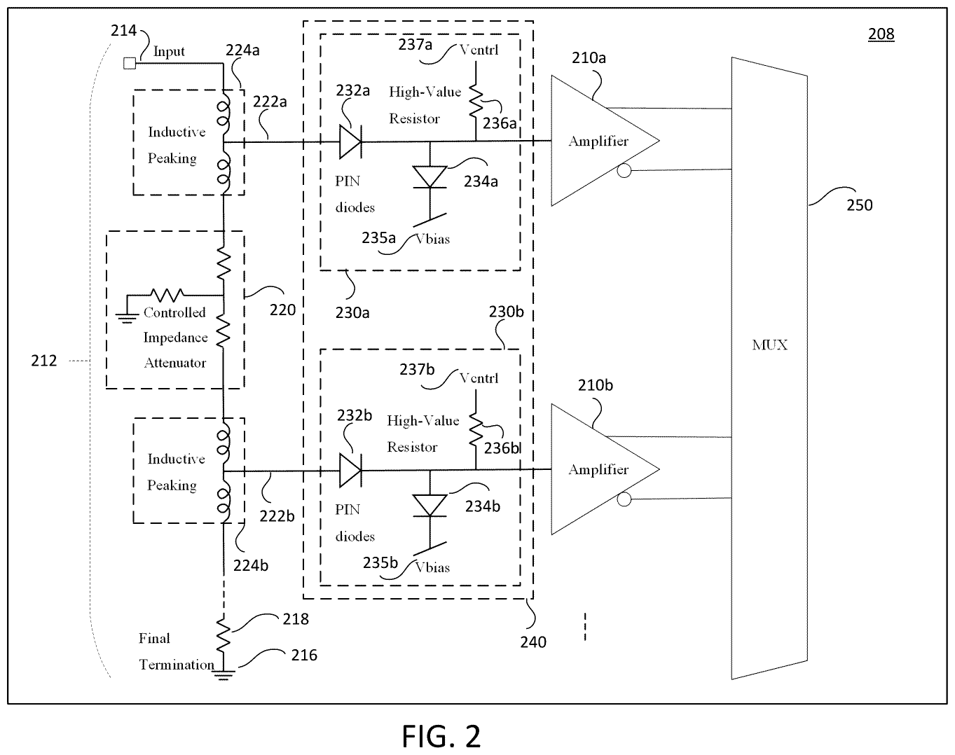

FIG. 2 shows an example of a tightly integrated analog front end 208 in a test and measurement instrument, according to some embodiments of the disclosure. Analog front end 208 may be an example of the analog front end 108 of FIG. 1. As shown in FIG. 2, the analog front end (AFE) includes one or more amplifiers 210a, 210b. The amplifiers may be single-ended or differential, according to different embodiments. The amplifiers are high-bandwidth, high-speed amplifiers, as they are amplifying the analog input signals up to full bandwidth of the test and measurement instrument, which in modern oscilloscopes may be in the multi-Gigahertz range. Accordingly, the amplifiers are physically implemented on a high-speed amplifier integrated circuit (IC) die; that is, a die made from a semiconductor material and according to a semiconductor processes that can support broadband analog signals and high-speed switching. According to some embodiments, the amplifiers are all physically implemented on the same common die; that is, all within the same IC.

The AFE 208 also includes a controlled-impedance signal path 212. The controlled-impedance signal path is shown in FIG. 2 progressing down the left side of the diagram from an input 214 to a reference voltage 216. The input 214 may be coupled to one of the input ports 102 from FIG. 1 to receive the analog signal received from the DUT at that input port. The reference voltage 216 may be ground, as shown in FIG. 2. The controlled-impedance signal path 216 may include a final termination resistor 218 to the reference voltage, such as the final termination resistor to ground, as shown in FIG. 2. In some embodiments, the controlled-impedance signal path 212 may have an impedance of 50 Ohms.

The controlled-impedance signal path 212 includes one or more controlled-impedance attenuators or attenuator stages 220. Each attenuator stage 220 is structured to attenuate the signal traversing the signal path 212 by a different predetermined attenuation factor, such as 100x, 50x, 25x, 10x, 5x, 2.5x, etc., for example. In some embodiments, such as the example shown in FIG. 2, each attenuator stage 220 may be implemented as a resistive divider circuit. Although the example embodiment illustrated in FIG. 2 only shows one attenuator stage 220, other embodiments may include one or more additional attenuator stages. The one or more controlled-impedance attenuator stages 220 are implemented on the same integrated circuit die as the amplifiers 210a, 210b. In some embodiments, a connection to the reference voltage/ground 216 of the controlled-impedance signal path, as well as the ground(s) of attenuator stage(s) 220, can be provided on the integrated circuit, e.g. as a reference voltage pin, which may then be connected “off-chip” to a programmable “Vterm” termination voltage.

The controlled-impedance signal path 212 also includes one or more signal taps 222a, 222b. The signal taps 222a, 222b tap the signal traversing the signal path 212 before or after each of the attenuators 220, such that the signal present at each signal tap 222a, 222b has gone through successive factors of attenuation. In the example shown in FIG. 2, the top-most signal tap 222a connects to the unattenuated input signal, while subsequent tap 222b connects to the input signal that has been attenuated by the predetermined attenuation factor of attenuator stage 220. According to other embodiments, there may be more than one signal tap and associated amplifier before the first attenuator stage. This may be useful to implement a distributed amplifier topology at high gains and/or to allow further gain switching in unattenuated (small input signal amplitude) use cases.

In some embodiments of the disclosure, the signal path 212 may also include inductive peaking circuits 224a, 224b at each respective signal tap 222a, 222b. Inductive peaking circuits 224a, 224b may comprise T-coils, or other inductive peaking methods, as known in the art. Each tap 222a, 222b, is inductively peaked to cancel the load capacitance of the associated amplifier 210a, 210b (when selected) or the OFF capacitance of the switch (when not selected).

According to some embodiments of the disclosure, the attenuator output(s) and subsequent stage(s) of the controlled-impedance signal path may be designed for progressively lower impedances (e.g. to reduce the amount of inductive peaking needed). Additionally, according to some embodiments, the attenuators may be designed for less attenuation at higher frequencies (aka “positive gain slope”) to compensate higher loss in the inductors and controlled-impedance input line at higher frequencies. This can allow a nominally flat response through many attenuator stages, increasing the flexibility of overall attenuator selection. Ins till other embodiments, some attenuators could be replaced with Continuous Time Linear Equalizers (CTLE) with even greater positive gain slope to allow selection of additional compensation for high-frequency loss in customer interconnect outside the oscilloscope.

The AFE 208 also includes a switching network 240. The switching network 240 may include a switching circuit 230a, 230b associated with each of the signal taps 222a, 222b, and the corresponding amplifiers 210a, 210b. The switching network 240 is structured to selectively couple one of the signal taps 222a, 222b, to the input of the corresponding amplifier 210a, 210b. The switching network 240 is physically implemented on the same integrated circuit die as the one or more amplifiers 210a, 210b. A controller (not shown) controls the operation of the switching network 240 in response to, for example, user inputs received at 130 or remote commands received at interface 134. In some embodiments, the controller may be the main processor 120.

The switching network 240 and the individual switching circuits 230a, 230b may be implemented using a variety of switching devices, according to various embodiments of the disclosure. In the example embodiment shown in FIG. 2, each switching circuit 230a, 230b uses PIN diodes 232a, 232b (basically, NPN base-collector junctions) as the switching devices, as they are generally available on a high-speed bipolar process suitable for a high-speed broadband amplifier used in an oscilloscope AFE. However, other solid-state switches such as FETs could also be used according to other embodiments (if available on the chosen process and of comparable R_{ON}·C_{OFF}). PIN diodes 232a, 232b may also be referred to as the input PIN diode or series PIN diode.

In the embodiment shown in FIG. 2, each switching circuit 230a, 230b also includes a shunt PIN diode 234a, 234b connected to a bias voltage Vbias 235a, 235b, and a relatively high value resistor 236a, 236b connected to a control voltage Vcntrl 237a, 237b. Vbias 235a, 235b is a nominally fixed bias voltage (e.g. +2V) that is capacitively coupled to ground to provide a very low AC impedance. If an amplifier's 210a, 210b respective control voltage Vcntrl 237a, 237b is set low (e.g. −5V) the respective input PIN diode 232a, 232b is forward biased (switched ON) and the shunt PIN diode 234a, 234b to Vbias is reverse biased (switched OFF). This passes the input signal from the respective signal tap 222a, 222b to the selected amplifier 210a, 210b. If an amplifier's Vcntrl is set high (e.g. +5V) the input PIN diode is OFF while the shunt PIN diode is ON. This configuration holds the amplifier input still and loads the signal tap with C_{OFF}, which can be chosen to match the amplifier's net C_{IN} (including the C_{OFF} of the shunt PIN), thus keeping the load on the tap nominally constant and maintaining the controlled-impedance nature of the controlled-impedance signal path 212.

A similar double PIN diode switch may be inserted in the differentially-opposed offset input of each amplifier (not shown), controlled by the same Vcntrl as the input switch for that amplifier. This provides a differentially-balanced voltage drop to the amplifier when selected, and zero drive to the amplifier when deselected (avoiding reverse Vbe stress to the amplifier devices).

In some embodiments, the series PIN diode switch 232a, 232b may be shunted with an impedance-matching (e.g. RC) network, rather than the shunt PIN diode 234a, 234b, to better match the amplifier input impedance across frequency.

In some embodiments of the disclosure, the polarity of the diode connections, Vcntrl, and Vbias could all be inverted while achieving the same functionality described above.

The PIN diodes switches shown before the first attenuator, 232a, 234a in FIG. 2, provide some level of protection (clamping) for positive-going electro-static-discharge ESD strikes on the input. According to some embodiments of the disclosure, having two amplifiers before the first attenuator, and one being implemented with the diode polarity inverted, the combination provides bi-directional ESD protection.

The selected amplifier 210a, 210b amplifies the signal from the respective signal tap 222a, 222b. In some embodiments, the amplifiers may all have predetermined amplification factors, or gains, which may be different from one another. In other embodiments, the amplifiers may have programmable gains. In still other embodiments, some of the amplifiers may have predetermined gains, and some may have programmable gains. In some embodiments, the amplifiers that are not selected may be powered down to minimize crosstalk and power dissipation. In some embodiments, more than one amplifier may be selected (and powered up) at a time. This may allow even more flexibility in selecting overall gain.

The amplified signals may then be output to a multiplexer 250. The output multiplexer (MUX) 250 selects the output from whichever input amplifier(s) are selected to observe the input signal (or attenuated version thereof). The output of the MUX 250 is then sent to one or more ADCs 104 for sampling and digitizing, as shown in FIG. 1.

According to some embodiments of the disclosure, the output MUX function can be moved to the input side of the amplifier by adding another series PIN diode (pointing the opposite direction) to the right of the high-value (aka long-tail) control resistor. The anodes of these diodes would then tie together and connect to a single long-tail pullup resistor and the amplifier input. This allows selection of only a single input tap at a time to drive the single amplifier stage, but minimizes amplifier layout area and eliminates the need for a separate output MUX function.

In operation, for small input signal amplitude, the first amplifier 210a is selected. For larger input signals, amplifiers that would otherwise be overdriven (and load the input signal in a non-linear fashion), e.g. 210a, are deselected and one or more subsequent amplifier(s) receiving a sufficiently attenuated signal for proper linear operation are selected, e.g. 210b. The allowed linear input signal amplitude is limited only by the breakdown voltage of the PIN diodes (or other switch devices) and not by the dynamic range or slew-limits of the amplifier devices.

FIG. 2 illustrates an example embodiment for receiving single-ended input signals. According to some embodiments of the disclosure, the entire structure described above may also be implemented differentially (i.e. two input paths, two switch networks, etc.).

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

Although specific aspects of the disclosure have been illustrated and described for purposes of illustration, it will be understood that various modifications may be made without departing from the spirit and scope of the disclosure.

What is claimed is:

1. A test and measurement instrument having an integrated analog front end, comprising:
one or more amplifiers, the one or more amplifiers implemented on a high-speed amplifier integrated circuit die;
a controlled-impedance signal path between an input and a reference voltage, the controlled-impedance signal path including one or more signal taps and one or more controlled-impedance attenuator stages, the one or more controlled-impedance attenuator stages implemented on the amplifier integrated circuit die; and
a switching network structured to selectively couple a signal tap of the controlled-impedance signal path to a respective amplifier of the one or more amplifiers, the switching network implemented on the amplifier integrated circuit die.

2. The test and measurement instrument of claim 1, further comprising a multiplexer having inputs coupled to the outputs of the one or more amplifiers and structured to output an amplified signal from a selected amplifier of the one or more amplifiers.

3. The test and measurement instrument of claim 2, wherein the multiplexer is implemented on the amplifier integrated circuit die.

4. The test and measurement instrument of claim 2, further comprising a controller structured to control operation of the switching network and the multiplexer.

5. The test and measurement instrument of claim 3, in which the controller is configured to turn off power to non-selected amplifiers of the one or more amplifiers.

6. The test and measurement instrument of claim 1, wherein the switching network comprises a switching circuit associated with each amplifier of the one or more amplifiers, the switching circuit comprising a PIN diode.

7. The test and measurement instrument of claim 1, wherein each amplifier of the one or more amplifiers has a different gain.

8. The test and measurement instrument of claim 1, wherein at least one of the one or more amplifiers has a predetermined gain.

9. The test and measurement instrument of claim 1, wherein at least one of the one or more amplifiers has a programmable gain.

10. The test and measurement instrument of claim 1, wherein each attenuator stage of the one or more attenuator stages has a different attenuation factor.

11. The test and measurement instrument of claim 1, wherein the one or more attenuator stages comprise multiple progressive attenuation stages each having progressively lower impedances.

12. The test and measurement instrument of claim 1, wherein the one or more attenuator stages are structured to have less attenuation at higher frequencies.

13. The test and measurement instrument of claim 1, wherein the controlled-impedance signal path includes one or more continuous time linear equalizers (CTLEs).

14. The test and measurement instrument of claim 1, wherein a first signal tap is connected to the controlled-impedance signal path between the input and a first attenuator stage to selectively couple an unattenuated input signal to a respective first amplifier.

15. The test and measurement instrument of claim 1, wherein the controlled-impedance signal path includes an inductive peaking circuit at each signal tap.

16. The test and measurement instrument of claim 1, wherein the reference voltage is ground.

17. The test and measurement instrument of claim 16, wherein the controlled-impedance signal path includes a termination resistor to ground.

18. The test and measurement instrument of claim 1, wherein the amplifier integrated circuit die includes a pin structured to receive a programmable termination voltage as the reference voltage.

19. The test and measurement instrument of claim 1, wherein the test and measurement instrument comprises an oscilloscope.

20. An integrated circuit providing an analog front end for an oscilloscope, comprising:
one or more amplifiers;
a controlled-impedance signal path between an input and a reference voltage, the controlled-impedance signal path including one or more signal taps and one or more controlled-impedance attenuator stages; and
a switching network structured to selectively couple a signal tap of the controlled-impedance signal path to a respective amplifier of the one or more amplifiers.
